(19) United States
(12) Patent Application Publication
(10) Pub. No.: US 2010/0068542 A1
(43) Pub. Date: Mar. 18, 2010

(54) METHOD OF MAKING INORGANIC OR INORGANIC/ORGANIC HYBRID FILMS

(75) Inventors: Clark I. Bright, Tucson, AZ (US); Stephen P. Maki, St. Paul, MN (US); Christopher S. Lyons, St. Paul, MN (US); Alan K. Nachtigal, St. Paul, MN (US); Maria L. Zelinsky, Eagan, MN (US); Judith M. Invie, Woodbury, MN (US); Andrew D. Dubner, St. Paul, MN (US); Mark J. Pellerite, Woodbury, MN (US); Thomas E. Wood, Stillwater, MN (US); Kenton D. Budd, Woodbury, MN (US)

Correspondence Address: 3M INNOVATIVE PROPERTIES COMPANY, PO BOX 33427, ST. PAUL, MN, 55133-3427, US

(73) Assignee: 3M INNOVATIVE PROPERTIES COMPANY, Saint Paul, MN (US)

(21) Appl. No.: 12/521,107

(22) PCT Filed: Dec. 28, 2007
(86) PCT No.: PCT/US2007/089088

§ 371 Date: Jun. 24, 2009

Related U.S. Application Data
(60) Provisional application No. 60/882,651, filed on Dec. 29, 2006.

(51) Int. Cl. B32B 27/36; C23C 16/22

(52) U.S. Cl. 428/480; 427/248.1

(57) ABSTRACT

A method for forming an inorganic or hybrid organic/inorganic layer on a substrate, which method comprises vaporizing a metal alkoxide, condensing the metal alkoxide to form a layer atop the substrate, and contacting the condensed metal alkoxide layer with water to cure the layer is disclosed.

### CROSS-REFERENCE TO RELATED APPLICATIONS

This application claims priority to Provisional Application Ser. No. 60/882,651, filed Dec. 29, 2006.

### FIELD

This invention relates to a process for manufacturing thin inorganic or hybrid inorganic/organic films.

### BACKGROUND

Inorganic or hybrid inorganic/organic layers have been used in thin films for electrical, packaging and decorative applications. These layers can provide desired properties such as mechanical strength, thermal resistance, chemical resistance, abrasion resistance, moisture barriers, oxygen barriers, and surface functionality that can affect wetting, adhesion, slippage, etc.

Inorganic or hybrid films can be prepared by a variety of production methods. These methods include liquid coating techniques such as solution coating, roll coating, dip coating, spray coating, spin coating, and dry coating techniques such as Chemical Vapor Deposition (CVD), Plasma Enhanced Chemical Vapor Deposition (PECVD), sputtering and vacuum processes for thermal evaporation of solid materials. Each of these methods has limitations.

Solution coating methods may require the use of solvents (organic or aqueous) to form the layer. Solvent usage can add cost to a process and can present environmental problems. Liquid phase methods may not be suitable for forming layers of immiscible materials or for mixtures of highly reactive materials because the materials can react immediately upon mixing in the liquid state.

Chemical vapor deposition methods (CVD and PECVD) form vaporized metal alkoxide precursors that undergo a reaction, when adsorbed on a substrate, to form inorganic coatings. These processes are limited to low deposition rates (and consequently low line speeds), and make inefficient use of the alkoxide precursor (much of the alkoxide vapor is not incorporated into the coating). The CVD process also requires high substrate temperatures, often in the range of 300-500° C., which may not be suitable for polymer substrates.

Sputtering has also been used to form metal oxide layers. This process is characterized by slow deposition rates allowing web speeds of just a few feet/min. Another characteristic of the sputtering process is its very low material utilization, because a major part of the solid sputtering target material does not become incorporated in the coating. The slow deposition rate, coupled with the high equipment cost, low utilization of materials, and very high energy consumption, makes it expensive to manufacture films by sputtering.

Vacuum processes such as thermal evaporation of solid materials (e.g., resistive heating or e-beam heating) also provide low metal oxide deposition rates. Thermal evaporation is difficult to scale up for roll wide web applications requiring very uniform coatings (e.g., optical coatings) and can require substrate heating to obtain quality coatings. Additionally, evaporation/sublimation processes can require ion-assist, which is generally limited to small areas, to improve the coating quality.

There remains a need for a method to prepare inorganic or hybrid inorganic/organic films on polymeric substrates that can be performed rapidly and at low cost.

### SUMMARY OF THE INVENTION

The present invention provides, in one aspect, a method for forming an inorganic or hybrid organic/inorganic layer on a substrate, which method comprises vaporizing a metal alkoxide, condensing the metal alkoxide to form a layer atop the substrate, and contacting the condensed metal alkoxide layer with water to cure the layer.

In a second aspect, the invention provides a method for forming a hybrid organic/inorganic layer on a substrate, which method comprises vaporizing a metal alkoxide, vaporizing an organic compound, condensing the vaporized alkoxide and vaporized organic compound to form a layer atop the substrate, and curing the layer.

These and other aspects of the invention will be apparent from the accompanying drawing and this specification. In no event, however, should the above summaries be construed as limitations on the claimed subject matter, which subject matter is defined solely by the attached claims, as may be amended during prosecution.

### BRIEF DESCRIPTION OF THE DRAWINGS

FIG. 1 is a schematic representation of a roll-to-roll apparatus for carrying out the disclosed method.

FIG. 2 is a schematic representation of a static, step-and-repeat, in-line or conveyor coater suitable for use in the disclosed method.

FIG. 3 is a reflectance spectrum of the sample prepared in Example 1.

FIG. 4 is a reflectance spectrum of the sample prepared in Example 12.

FIG. 5 are reflectance spectra of the samples prepared in Examples 19-21.

FIG. 6 are reflectance spectra of the samples prepared in Examples 42-45.

FIG. 7 is a reflectance spectrum of the sample prepared in Example 46.

FIG. 8 are reflectance spectra of the samples prepared in Examples 47-53.

### DETAILED DESCRIPTION

The words “a”, “an”, and “the” are used interchangeably with “at least one” to mean one or more of the elements being described. By using words of orientation such as “atop”, “on”, “covering”, “uppermost”, “underlying” and the like for the location of various elements in the disclosed coated articles, we refer to the relative position of an element with respect to a horizontally-disposed, upwardly-facing substrate. It is not intended that the substrate or articles should have any particular orientation in space during or after manufacture.

The term “polymer” includes homopolymers and copolymers, as well as homopolymers or copolymers that may be formed in a miscible blend, e.g., by coextrusion or by reaction, including, e.g., transesterification. The term “copolymer” includes both random and block copolymers.

The term “crosslinked” polymer refers to a polymer in which the polymer chains are joined together by covalent chemical bonds, usually via crosslinking molecules or groups, to form a network polymer. A crosslinked polymer is generally characterized by insolubility, but may be swellable in the presence of an appropriate solvent.

The term “water” refers to water vapor, liquid water or a plasma containing water vapor.

The term “cure” refers to a process that causes a chemical change, e.g., a reaction with water, to solidify a film layer or increase its viscosity.

The term “metal” includes a pure metal or a metal alloy.

The term “optically clear” refers to a laminated article in which there is no visibly noticeable distortion, haze or flaws as detected by the naked eye at a distance of about 1 meter, preferably about 0.5 meters.

The term “optical thickness” when used with respect to a layer refers to the physical thickness of the layer times its in-plane index of refraction. In some optical designs a preferred optical thickness is about ¼ the wavelength of the center of the desired waveband for transmitted or reflected light.

A variety of substrates can be employed. In one embodiment, the substrates are light-transmissive and can have a visible light transmission of at least about 50% at 550 nm. Exemplary substrates are flexible plastic materials including thermoplastics such as polyesters (e.g., poly(ethylene terephthalate) (PET) or poly(ethylene naphthalates)), polyacrylates (e.g., poly(methyl methacrylate)), polycarbonates, polypropylenes, high or low density polyethylenes, polysulfones, poly(ether sulfone)s, polyurethanes, polyamides, poly(vinyl butyral), poly(vinyl chloride), fluoropolymers (e.g., poly(vinylidene difluoride) and polytetrafluoroethylene), poly(ethylene sulfide), and thermoset materials such as epoxies, cellulose derivatives, polyimide, poly(imide benzoxazole) and polybenzoxazole. The substrate can also be a multilayer optical film (“MOF”), such as those described in U.S. Patent Application Publication No. 2004/0032658 A1.

In one embodiment, the disclosed films can be prepared on a substrate including PET. The substrate may have a variety of thicknesses, e.g., about 0.01 to about 1 mm. The substrate may however be considerably thicker, for example, when a self-supporting article is desired. Such articles can conveniently also be made by laminating or otherwise joining a disclosed film made using a flexible substrate to a thicker, inflexible or less flexible supplemental support.

Suitable metal alkoxides for forming a layer on a substrate are compounds that can be volatilized and condensed on the substrate. After condensation the alkoxides can be cured via reaction with water to form a layer having one or more desirable properties. Exemplary metal alkoxide compounds can have the general formula R¹ₓM-(OR²)_{y-x} where each R¹ is independently C₁-C₂₀alkyl, (C₃-C₈)cycloalkyl, (C₂-C₇)heterocycle, (C₂-C₇)heterocycle(C₁-C₈)alkylene-, (C₆-C₁₀)aryl, (C₆-C₁₀)aryl(C₁-C₈)alkylene-, (C₅-C₉)heteroaryl, or (C₅-C₉)heteroaryl(C₁-C₈)alkylene-, and each R² is independently (C₁-C₆)alkyl, or (C₂-C₆)alkenyl, optionally substituted with hydroxyl or oxo, or two OR² groups can form a ring together with the atom to which they are attached.

The R¹ groups can be optionally substituted with one or more substituent groups, wherein each substituent is independently (C₁-C₄)alkyl, oxo, halo, —OR^{a}, —SR^{a}, cyano, nitro, trifluoromethyl, trifluoromethoxy, (C₃-C₈)cycloalkyl, (C₂-C₇)heterocycle or (C₂-C₇)heterocycle (C₁-C₈)alkylene-, (C₆-C₁₀)aryl, (C₆-C₁₀)aryl(C₁-C₈)alkylene-, (C₅-C₉)heteroaryl, (C₅-C₉)heteroaryl(C₁-C₈)alkylene-, —CO₂R^{a}, R^{a}C(═O)O—, R^{a}C(═O)—, —OCO₂R^{a}, R^{b}R^{c}NC(═O)O—, R^{a}OC(═O)N(R^{b})—, R^{b}R^{c}N—, R^{b}R^{c}NC(═O)—, R^{a}C(═O)N(R^{b})—, R^{b}R^{c}NC(═O)N(R^{b})—, R^{b}R^{c}NC(═S)N(R^{b})—, —OPO₃R^{a}, R^{a}OC(═S)—, R^{a}C(═S)—, —SSR^{a}, R^{a}S(═O)—, —NNR^{b}, —OPO₂R^{a}, or two R¹ groups can form a ring together with the atom to which they are attached. Each R^{a}, R^{b} and R^{c} is independently hydrogen, (C₁-C₈)alkyl, or substituted (C₁-C₈)alkyl wherein the substituents include 1, 2, or 3 (C₁-C₈)alkoxy, (C₃-C₈)cycloalkyl, (C₁-C₈)alkylthio, amino, aryl, or aryl(C₁-C₈)alkylene, or R^{b} and R^{c}, can form a ring together with the nitrogen atom to which they are attached. Exemplary rings include pyrrolidino, piperidino, morpholino, or thiomorpholino. Exemplary halo groups include fluoro, chloro, or bromo. The R¹ and R² alkyl groups can be straight or branched chains. M represents a metal, x is 0, 1, 2, 3, 4, or 5, and y is the valence number of the metal, e.g., y can be 3 for aluminum, 4 for titanium and zirconium, and may vary depending upon the oxidation state of the metal, provided that y−x≧1, e.g., there must be at least one alkoxy group bonded to the metal atom.

Exemplary metals include aluminum, antimony, arsenic, barium, bismuth, boron, cerium, gadolinium, gallium, germanium, hafnium, indium, iron, lanthanum, lithium, magnesium, molybdenum, neodymium, phosphorus, silicon, sodium, strontium, tantalum, thallium, tin, titanium, tungsten, vanadium, yttrium, zinc, and zirconium, or a mixture thereof. Several metal alkoxides, e.g., organic titanates and zirconates, are available from DuPont Co. under the Tyzor™ trademark. Non-limiting examples of specific metal alkoxides include tetra(methoxy) titanate, tetra(ethoxy) titanate, tetra(isopropoxy) titanate, tetra(n-propoxy)titanate, tetra(butoxy) titanate, 2-ethylhexyloxy titanate, octylene glycol titanate, poly(n-butoxy) titanate, triethanolamine titanate, n-butyl zirconate, n-propyl zirconate, titanium acetyl acetonate, ethyl acetoacetic ester titanate, isostearoyl titanate, titanium lactate, zirconium lactate, zirconium glycolate, methyltriacetoxy silane, fluorinated silanes (e.g., such as fluorinated polyether silanes disclosed in U.S. Pat. No. 6,991,826), tetra(n-propoxy) zirconate, and mixtures thereof. Additional examples include vaporizable prepolymerized forms of the above metal alkoxides including dimers, trimers, and longer oligomers including polydimethoxysiloxane and polybutyl titanate. Additional metal alkoxides include methoxy, ethoxy, n-propoxy, butoxy, acetoxy, and isopropoxy functionalized metal atoms, and prepolymerized forms of those metal alkoxides, e.g., poly(n-butoxy titanate). Other metal alkoxides that can be polymerized include tetra(ethoxy) titanate, tetra(n-propoxy) titanate, tetra(isopropoxy) titanate, methyltriacetoxy silane, fluorinated silanes, polydimethoxy silane, and tetra(n-propoxy) zirconate. Alkoxide mixtures may be selected to provide a preselected property, e.g., index of refraction or predetermined hardness, for the inorganic or hybrid organic/inorganic layer.

The metal alkoxides can be vaporized using a variety of methods known in the art. Exemplary methods include evaporation, e.g., flash evaporation, using techniques like those disclosed in U.S. Pat. Nos. 4,954,371 and 6,045,864, sublimation, and the like. The evaporation can be conducted under vacuum or at atmospheric pressure. Carrier gas flows (optionally heated) may be added to the evaporator to reduce the partial pressure of the metal alkoxide vapor or to increase the evaporation rate. The alkoxide may be condensed onto the substrate at a temperature below the condensation point of the vapor stream.

The condensed alkoxide layer is cured by contacting the layer with water. For example, the layer can be contacted with water vapor, liquid water or a plasma containing water vapor. Curing can be enhanced with heat. Heat can be provided using any suitable source, e.g., an infra red heater or a catalytic combustion burner. The catalytic combustion burner can also provide water vapor. Additional energy can be provided by UV or vacuum UV light input into the condensed alkoxide layer during the curing process.

The curing reactions may be accelerated with vaporizable catalysts. Exemplary catalysts include organic acids such as acetic acid and methane sulfonic acid, photoacid generators such as triphenyl sulfonium and diphenyl iodonium compounds, basic materials such as ammonia and photobase generators. Photoactive catalysts can be activated by exposure to UV light. The catalyst can condense into the coating layer or adsorb on the surface to promote the curing reactions.

In another embodiment, a metal alkoxide and an organic compound can be vaporized, condensed on the substrate, and cured. In one embodiment, the curing can include contacting the layer with water. Curing can involve reaction of the alkoxide with water to solidify the film layer or increase its viscosity together with polymerization of the organic compound to form an intermixed film layer. Curing can also be conducted in sequential steps. The components of the layer can be pre-reacted to form a volatilizable oligomer prior to deposition. Curing can also include reaction of the components of the layer (alkoxide and organic compound) together with or without water to form an organometallic copolymer. The films prepared having an organometallic copolymer may be designed to exhibit controlled properties such as viscosity, etc., or form films with a set of properties between the properties obtained when the films are prepared by separate deposition of the two components. The hybrid films thus prepared can provide a layer or surface having beneficial properties such as refractive index to affect optical transmission, reflection, or absorption, surface protection (hardness or lubrication) properties, low or high surface energy to affect wettability or interactions with other materials, low adhesion (release) or high adhesion to contacting materials, electrical conductivity or resistivity, anti-soiling and easy-clean, and surface functionalization.

The organic compounds can be vaporized using any methods like those described above for vaporizing the metal alkoxide. The alkoxide and the organic compound can be evaporated together to form a mixed vapor or they can be evaporated separately and mixed in the vapor phase. In applications where the alkoxide and the organic compound (or another metal alkoxide) are immiscible, it may be desirable to mix these materials in the vapor phase after separate evaporation. The alkoxide and organic compound may be condensed onto the substrate at a temperature below the condensation point of the vapor stream.

Exemplary organic compounds include esters, vinyl compounds, alcohols, carboxylic acids, acid anhydrides, acyl halides, thiols, amines and mixtures thereof. Non-limiting examples of esters include (meth)acrylates, which can be used alone or in combination with other multifunctional or monofunctional (meth)acrylates. Exemplary acrylates include hexanediol diacrylate, ethoxyethyl acrylate, phenoxyethyl acrylate, cyanoethyl (mono)acrylate, isobornyl acrylate, octadecyl acrylate, isodecyl acrylate, lauryl acrylate, beta-carboxyethyl acrylate, tetrahydrofurfuryl acrylate, dinitrile acrylate, pentafluorophenyl acrylate, nitrophenyl acrylate, 2-phenoxyethyl acrylate, 2,2,2-trifluoromethyl acrylate, diethylene glycol diacrylate, triethylene glycol diacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, trimethylol propane triacrylate, ethoxylated trimethylol propane triacrylate, propylated trimethylol propane triacrylate, tris(2-hydroxyethyl)-isocyanurate triacrylate, pentaerythritol triacrylate, pentaerythritol tetraacrylate, phenylthioethyl acrylate, naphthyloxyethyl acrylate, Ebecryl 130 cyclic diacrylate (from Cytec Industries Inc., New Jersey, U.S.A.), epoxy acrylate CN120E50 (from Sartomer Company, Exton, Pa., U.S.A.), the corresponding methacrylates of the acrylates listed above and mixtures thereof. Exemplary vinyl compounds include vinyl ethers, styrene, vinyl naphthylene and acrylonitrile. Exemplary alcohols include hexanediol, naphthalenediol, 2-hydroxyacetophenone, 2-hydroxy-2-methyl-1-phenyl-1-propanone, and hydroxyethylmethacrylate. Exemplary vinyl compounds include vinyl ethers, styrene, vinyl naphthylene and acrylonitrile. Exemplary carboxylic acids include phthalic acid and terephthalic acid, (meth)acrylic acid). Exemplary acid anhydrides include phthalic anhydride and glutaric anhydride. Exemplary acyl halides include hexanedioyl dichloride, and succinyl dichloride. Exemplary thiols include ethyleneglycol-bisthioglycolate, and phenylthioethylacrylate. Exemplary amines include ethylene diamine and hexane 1,6-diamine.

Metal layers can be made from a variety of materials. Exemplary metals include elemental silver, gold, copper, nickel, titanium, aluminum, chromium, platinum, palladium, hafnium, indium, iron, lanthanum, magnesium, molybdenum, neodymium, silicon, germanium, strontium, tantalum, tin, titanium, tungsten, vanadium, yttrium, zinc, zirconium or alloys thereof. In one embodiment, silver can be coated on a cured alkoxide layer. When two or more metal layers are employed, each metal layer can be the same or different from another layer, and need not have the same thickness. In one embodiment, the metal layer or layers are sufficiently thick so as to be continuous, and sufficiently thin so as to ensure that the metal layer(s) and articles employing these layer(s) will have a desired degree of visible light transmission. For example, the physical thickness (as opposed to the optical thickness) of the visible-light-transmissive metal layer or layers may be from about 5 to about 20 nm, from about 7 to about 15 nm, or from about 10 nm to about 12 nm. The thickness range also will depend on the choice of metal. The metal layer(s) can be formed by deposition on the above-mentioned substrate or on the inorganic or hybrid layer using techniques employed in the metallizing art such as sputtering (e.g., rotary or planar magnetron sputtering), evaporation (e.g., resistive or electron beam evaporation), chemical vapor deposition (CVD), metalorganic CVD (MOCVD), plasma-enhanced, assisted, or activated CVD (PECVD), ion sputtering, plating and the like.

Polymeric layers can be formed from a variety of organic materials. The polymeric layer may be crosslinked in situ after it is applied. In one embodiment, the polymeric layer can be formed by flash evaporation, vapor deposition and polymerization of a monomer using, for example, heat, plasma, UV radiation or an electron beam. Exemplary monomers for use in such a method include volatilizable (meth)acrylate monomers. In a specific embodiment, volatilizable acrylate monomers are employed. Suitable (meth)acrylates will have a molecular weight that is sufficiently low to allow flash evaporation and sufficiently high to permit condensation on the substrate. If desired, the additional polymeric layer can also be applied using conventional methods such as plasma deposition, solution coating, extrusion coating, roll coating (e.g., gravure roll coating), spin coating, or spray coating (e.g., electrostatic spray coating), and if desired crosslinking or polymerizing, e.g., as described above. The desired chemical composition and thickness of the additional layer will depend in part on the nature of the substrate and the desired purpose for the article. Coating efficiency can be improved by cooling the substrate.

Films prepared using the disclosed method have a variety of uses including the fabrication of antireflective coatings for optical devices (e.g., such as displays, windows, instrument panels, and ophthalmic lenses), beam splitters, edge filters, subtraction filters, bandpass filters, Fabry-Perot tuned cavities, light-extracting-films, reflectors and other optical coating designs. The disclosed method enables the preparation of films having a wide range of refractive indices from less than 1.45 to greater than 2.0. Additional layers can be applied to the hybrid organic/inorganic layer to provide properties such as anti-reflective properties or to prepare a reflective stack having color shifting properties.

Films of the invention with color shifting properties can be used in security devices, for a variety of applications such as tamperproof images in value documents (e.g., currency, credit cards, stock certificates, etc.), driver's licenses, government documents, passports, ID badges, event passes, affinity cards, product identification formats and advertising promotions for verification or authenticity, e.g., tape cassettes, playing cards, beverage containers, brand enhancement images which can provide a floating or sinking or a floating and sinking image of the brand, information presentation images in graphics applications such as kiosks, night signs and automotive dashboard displays, and novelty enhancement through the use of composite images on products such as business cards, hang-tags, art, shoes and bottled products.

The security devices or other color shifting articles can include an image. Images can be formed by a variety of methods known in the art including etching, printing, or photographic techniques. Exemplary etching techniques include laser etching, abrasive and chemical etching. Exemplary printing techniques include screen printing, inkjet printing, thermal transfer printing, letterpress printing, offset printing, flexographic printing, stipple printing, laser printing, and so forth, using a variety of inks, including one and two component inks, oxidatively drying and UV-drying inks, dissolved inks, dispersed inks, and 100% solid ink systems. Exemplary photographic techniques include positive and negative photographic imaging and development. The image can be applied to the substrate or one or more of the layers in a reflective stack prior to the formation of any subsequent layer(s), or the image can be imprinted into the reflective stack using techniques like those disclosed in U.S. Pat. No. 6,288,842. The image should be formed such that it may be viewed or illuminated through the reflective stack. Images may be formed so as to have a restricted viewing angle. In other words, the image would only be seen if viewed from a particular direction, e.g., at normal incidence or at minor angular variations from the chosen direction. The image can be made to appear to be suspended, or float, above, in the plane of, or below the film.

Films prepared using the disclosed method can be used to provide low-surface energy anti-soil or anti-smudge properties for display devices, windows, and ophthalmic lenses. Films prepared using the disclosed method can be used to provide dielectric properties in electrical and electronic devices.

The smoothness and continuity of the film and the adhesion of subsequently applied layers to the substrate can be enhanced by appropriate pretreatment of the substrate or application of a priming or seed layer prior to forming the inorganic or hybrid layer. Modification of the surface to create hydroxyl or amine functional groups is particularly desirable. Methods for surface modification are known in the art. In one embodiment, a pretreatment regimen involves electrical discharge pretreatment of the substrate in the presence of a reactive or non-reactive atmosphere (e.g., plasma, glow discharge, corona discharge, dielectric barrier discharge or atmospheric pressure discharge), chemical pretreatment, or flame pretreatment. These pretreatments can help ensure that the surface of the substrate will be receptive to the subsequently applied layers. In one embodiment, the method can include plasma pretreatment. For organic surfaces, plasma pretreatments can include nitrogen or water vapor. Another pretreatment regimen involves coating the substrate with an inorganic or organic base coat layer optionally followed by further pretreatment using plasma or one of the other pretreatments described above. In another embodiment, organic base coat layers, and especially base coat layers based on crosslinked acrylate polymers are employed. The base coat layer can be formed by flash evaporation and vapor deposition of a radiation-crosslinkable monomer (e.g., an acrylate monomer), followed by crosslinking in situ (using, for example, an electron beam apparatus, UV light source, electrical discharge apparatus or other suitable device), as described in U.S. Pat. Nos. 4,696,719, 4,722,515, 4,842,893, 4,954,371, 5,018,048, 5,032,461, 5,097,800, 5,125,138, 5,440,446, 5,547,908, 6,045,864, 6,231,939 and 6,214,422; in published PCT Application No. WO 00/26973; in D. G. Shaw and M. G. Langlois, “A New Vapor Deposition Process for Coating Paper and Polymer Webs”, 6th International Vacuum Coating Conference (1992); in D. G. Shaw and M. G. Langlois, “A New High Speed Process for Vapor Depositing Acrylate Thin Films: An Update”, Society of Vacuum Coaters 36th Annual Technical Conference Proceedings (1993); in D. G. Shaw and M. G. Langlois, “Use of Vapor Deposited Acrylate Coatings to Improve the Barrier Properties of Metallized Film”, Society of Vacuum Coaters 37th Annual Technical Conference Proceedings (1994); in D. G. Shaw, M. Roehrig, M. G. Langlois and C. Sheehan, “Use of Evaporated Acrylate Coatings to Smooth the Surface of Polyester and Polypropylene Film Substrates”, RadTech (1996); in J. Affinito, P. Martin, M. Gross, C. Coronado and E. Greenwell, “Vacuum deposited polymer/metal multilayer films for optical application”, Thin Solid Films 270, 43-48 (1995); and in J. D. Affinito, M. E. Gross, C. A. Coronado, G. L. Graff, E. N. Greenwell and P. M. Martin, “Polymer-Oxide Transparent Barrier Layers”, Society of Vacuum Coaters 39th Annual Technical Conference Proceedings (1996). If desired, the base coat can also be applied using conventional coating methods such as roll coating (e.g., gravure roll coating) or spray coating (e.g., electrostatic spray coating), then crosslinked using, for example, heat, UV radiation or an electron beam. The desired chemical composition and thickness of the base coat layer will depend in part on the nature of the substrate. For example, for a PET substrate, the base coat layer can be formed from an acrylate monomer and may for example have a thickness of only a few nm up to about 20 micrometers.

The films can be subjected to post-treatments such as heat treatment, UV or vacuum UV (VUV) treatment, or plasma treatment. Heat treatment can be conducted by passing the film through an oven or directly heating the film in the coating apparatus, e.g., using infrared heaters or heating directly on a drum. Heat treatment may for example be performed at temperatures from about 30° C. to about 200° C., about 35° C. to about 150° C., or about 40° C. to about 70° C.

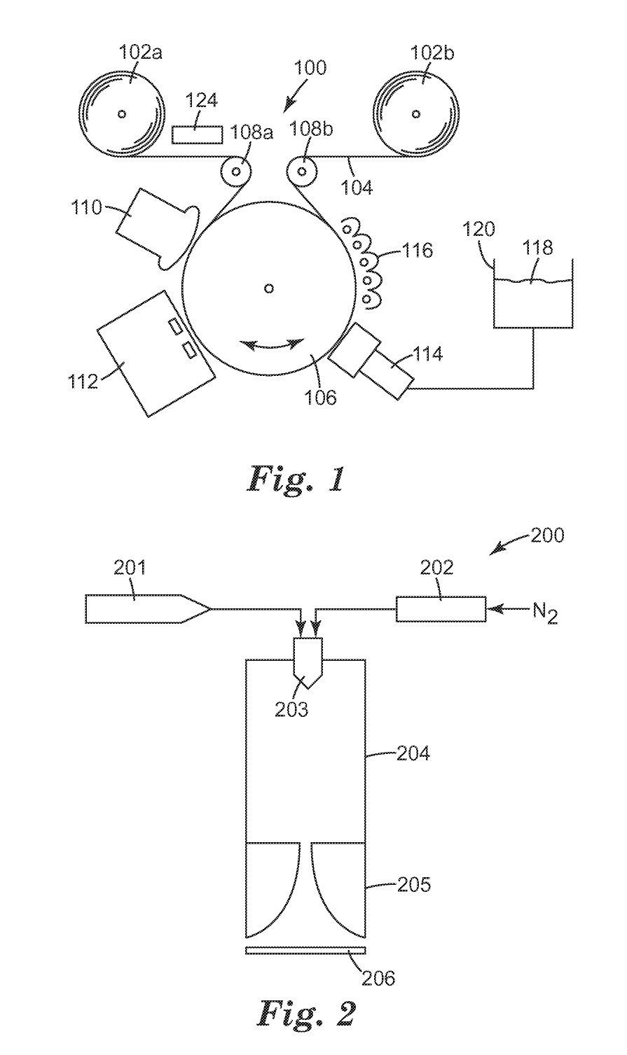

An example of an apparatus 100 that can conveniently be used to perform the disclosed method is shown in FIG. 1. Powered reels 102a and 102b move substrate 104 back and forth through apparatus 100. Temperature-controlled rotating drum 106 and idlers 108a and 108b carry substrate 104 past plasma source 110, sputtering applicator 112, evaporator 114, and UV lamps 116. Liquid alkoxide 118 is supplied to evaporator 114 from reservoir 120. Optionally, liquid 118 can be discharged into the evaporator through an atomizer (not shown). Optionally, gas flows (e.g., nitrogen, argon, helium) can be introduced into the atomizer or into the evaporator (not shown in FIG. 1). Water can be supplied through the gas manifold in plasma source 110 after the alkoxide layer is condensed. Infrared lamp 124 can be used to heat the substrate prior to or after application of one or more layers. Successive layers can be applied to the substrate 104 using multiple passes (in either direction) through apparatus 100. Optional liquid monomer can be applied through evaporator 114 or a separate evaporator (not shown) supplied from reservoir 120 or a separate reservoir (not shown). UV lamps 116 can be used to produce a crosslinked polymer layer from the monomer. Apparatus 100 can be enclosed in a suitable chamber (not shown in FIG. 1) and maintained under vacuum or supplied with a suitable inert atmosphere in order to discourage oxygen, dust and other atmospheric contaminants from interfering with the various pretreatment, alkoxide coating, crosslinking and sputtering steps.

Another example of an apparatus 200 that can conveniently be used to perform the disclosed method is shown in FIG. 2. Liquid alkoxide in syringe pump 201 is mixed with nitrogen from heater 202 in atomizer 203 which atomizes the alkoxide. The resulting droplets can be delivered to vaporizer 204 where the droplets are vaporized. The vapor passes through diffuser 205 and condenses on substrate 206. The substrate 206 with condensed alkoxide is treated in-place or removed and treated with water, to cure the alkoxide in a subsequent step. A catalytic burner (not shown) can be used to supply heat and water vapor. Apparatus 200 can be used to apply optional liquid monomer through syringe pump 201 or a separate syringe pump (not shown). The condensed monomer on substrate 206 is crosslinked in a subsequent step.

For some applications, it may be desirable to alter the appearance or performance of the film, such as by laminating a dye containing layer to the inorganic or hybrid film, applying a pigmented coating to the surface of the inorganic or hybrid film, or including a dye or pigment in one or more of the materials used to make the inorganic or hybrid film. The dye or pigment can absorb in one or more selected regions of the spectrum, including portions of the infrared, ultraviolet or visible spectrum. The dye or pigment can be used to complement the properties of the inorganic or hybrid film. A particularly useful pigmented layer that can be employed in the films is described in published PCT Application No. WO 2001/58989. This layer can be laminated, extrusion coated or coextruded as a skin layer on the disclosed film. The pigment loading level can be varied, e.g., between about 0.01 and about 2% by weight, to vary the visible light transmission as desired. The addition of a UV absorptive cover layer can also be desirable in order to protect any inner layers of the article that may be unstable when exposed to UV radiation. Other functional layers or coatings that can be added to the inorganic or hybrid film include an optional layer or layers to make the article more rigid.

The uppermost layer of the article is optionally a suitable protective layer. If desired, the protective layer can be applied using conventional coating methods such as roll coating (e.g., gravure roll coating), spin coating, or spray coating (e.g., electrostatic spray coating), then crosslinked using, for example, UV radiation. The protective layer can also be formed by flash evaporation, vapor deposition and crosslinking of a monomer as described above. Volatilizable (meth)acrylate monomers are suitable for use in such a protective layer. In a specific embodiment, volatilizable acrylate monomers are employed.

The invention is further illustrated in the following examples, in which all parts, percentages and ratios are by weight unless otherwise indicated.

### Example 1

### Tetra(ethoxy) Titanate

A thin film was formed from tetra(ethoxy) titanate (DuPont Tyzor ET) using a vapor coater similar to the coater illustrated schematically in FIG. 1. The substrate was a 4-mil thick, 18-inch wide polyester (DuPont 454). In the first pass through the coater, the substrate was plasma treated with water vapor plasma at 0.3 Torr, operating at 400 kHz, a net power of 400 W and a line speed of 40 fpm.

Tetra(ethoxy) titanate was dispensed into a glass jar and placed into a vacuum bell jar for degassing. The bell jar was evacuated to 0.012 Torr for a period of 20 minutes. After degassing, the bell jar was vented to atmosphere and the liquid loaded into a syringe. The syringe was mounted on a syringe pump and connected to an atomizer/evaporator system as described in “METHOD FOR ATOMIZING MATERIAL FOR COATING PROCESSES” (PCT/US2006/049432, filed Dec. 28, 2006). For the second pass through the coater, the tetra(ethoxy) titanate was pumped to the atomizer at a flow rate of 1.0 ml/min. The flow rate of nitrogen gas to the atomizer was 15 sccm. The tetra(ethoxy) titanate was atomized into fine droplets and flash evaporated when the droplets contacted the hot evaporator wall surface (150° C.). The vapor flow exited a 16-inch-wide coating die and condensed on the substrate moving at a line speed of 16 fpm. The process drum temperature was 158° F. The condensed layer of tetra(ethoxy) titanate was immediately exposed to water vapor in the vacuum chamber to cure the coating. A continuous flow of distilled water vapor was introduced into the chamber from a temperature controlled flask of liquid water held at 80° F. The chamber throttle valve kept the chamber pressure (mostly water vapor) at 0.95 Torr.

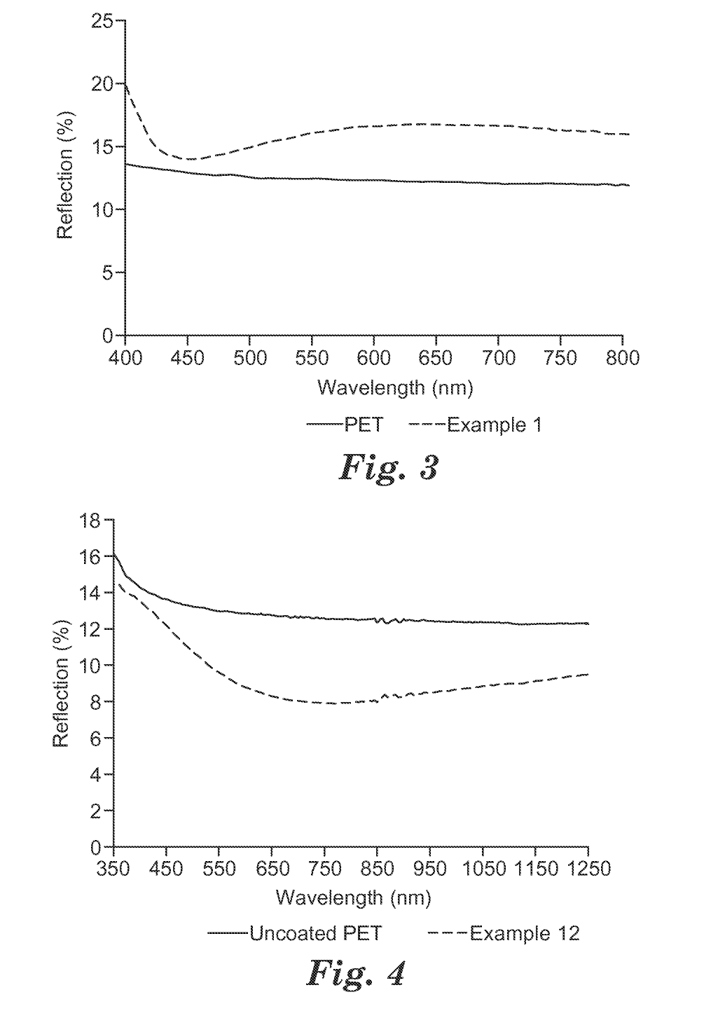

The reflectance spectrum of Sample 1 is shown in FIG. 3. The cured organotitanate film has higher reflectance than the uncoated PET substrate, indicating a higher refractive index than that of the PET (n=1.65). From the reflectance data, the thickness and refractive index of the film were calculated to be about 82 nm and 1.82, respectively at a wavelength of 600 nm.

### Example 2

### Tetra(ethoxy) Titanate

A polyester substrate (DuPont 454) was coated using the procedure of Example 1, with the following changes: The coating material, tetra(ethoxy) titanate, was handled in a nitrogen-purged glove box with vacuum capability to degas the liquid and was not exposed to atmospheric moisture during the degas and syringe loading process. The water vapor was continuously flowing into the coater chamber via a mass flow controller (MKS VODM) at a flow rate of 1000 sccm. The process drum temperature was 60° F. The evaporator temperature was 200° C. Nitrogen gas was introduced as a carrier gas in the evaporator at a flow rate of 67 sccm. The substrate speed was 18.7 fpm. The throttle valve kept the chamber pressure at 2.0 Torr. From the reflectance data, the thickness and refractive index of the film were calculated to be about 79 nm and 1.80, respectively, at a wavelength of 570 nm.

### Example 3

### Tetra(isopropoxy) titanate

A polyester substrate (DuPont 454) was coated using the procedure of Example 1, with the following changes: The coating material was tetra(isopropoxy) titanate (DuPont Tyzor TPT). The process drum temperature was 63° F. The evaporator temperature was 100° C. The substrate speed was 15 fpm. The throttle valve kept the chamber pressure at 1.0 Torr. The first pass plasma pretreatment gas was nitrogen. From the reflectance data, the thickness and refractive index of the film were calculated to be about 59 nm and 1.89, respectively.

### Examples 4-6

### Tetra(n-propoxy) Titanate and Tetra(n-butoxy) Zirconate

A polyester substrate (DuPont 453, 2-mil) was coated using the procedure of Example 1, with the following changes: Two monomer syringes and syringe pumps were used, one containing tetra(n-propoxy) titanate (DuPont Tyzor NPT) and the other containing tetra(n-butoxy) zirconate (DuPont Tyzor NBZ). The syringes containing the alkoxides were connected in parallel to enable either syringe separately or both together (mixed as liquids) to pump material to the atomizer. The evaporator temperature was 275° C. The remaining process conditions, coating thickness and refractive index for Examples 4-6 are described in Table 1, below.

TABLE 1
Process Conditions and Coating Characterization

| | | DuPont | | | |
|---|---|---|---|---|---|
| | DuPont | Tyzor | | | |
| | Tyzor NPT | NBZ Flow | Substrate | Coating | Coating |
| Example | Flow Rate | Rate | Speed | Index of | Thickness |
| No. | (ml/min) | (ml/min) | (fpm) | Refraction | (nm) |
| 4 | 1.0 | 0 | 16 | 1.81 | 62 |
| 5 | 0.4 | 0.68 | 10 | 1.72 | 183 |
| 6 | 0 | 1.133 | 10 | 1.69 | 165 |

### Example 7

### Tetra(n-propoxy) Zirconate

A polyester substrate (DuPont 454, 4-mil) was coated using the procedure of Example 2, with the following changes: The coating material was tetra(n-propoxy) zirconate (Tyzor NPZ). The evaporator temperature was 275° C. The substrate line speed was 9.5 fpm. The liquid Tyzor NPZ flow rate was 1.05 ml/min. The throttle valve kept the chamber pressure at 3 Torr. The nitrogen flow into the atomizer was 10 sccm. From the reflectance data, the thickness and refractive index of the film were calculated to be about 82 nm and 1.72, respectively, at a wavelength of 565 nm.

### Examples 8-10

### Tetra(n-propoxy) Zirconate and Tetra(ethoxy) Titanate

A polyester substrate (DuPont 454, 4-mil) was coated using the procedure of Example 2, with the following changes: Two monomer syringes and syringe pumps were used, one containing tetra(n-propoxy) zirconate (DuPont Tyzor NPZ) and the other containing tetra(ethoxy) titanate (DuPont Tyzor ET). The syringes containing the alkoxides were connected in parallel to enable either syringe separately or both together to pump material to the atomizer. The evaporator temperature was 275° C. The coating die was 12-inches wide. The substrate line speed was 12 fpm. The nitrogen flow into the atomizer was 10 sccm. The remaining process conditions, coating thickness and refractive index for Examples 8-10 are described in Table 2, below.

TABLE 2
Process Conditions and Coating Characterization

| | | DuPont | | | |
|---|---|---|---|---|---|
| | DuPont | Tyzor | | | |
| Exam- | Tyzor NPZ | ET | | Coating | Coating |
| ple | Flow Rate | Flow Rate | Wavelength | Index of | Thickness |
| No. | (ml/min) | (ml/min) | % Rₘₐₓ (nm) | Refraction | (nm) |
| 8 | 0.670 | 0.188 | 530 | 1.70 | 78 |
| 9 | 0.446 | 0.375 | 610 | 1.69 | 90 |
| 10 | 0.223 | 0.563 | 550 | 1.74 | 79 |

### Example 11

### Polydimethoxysiloxane and Tetra(ethoxy) Titanate

A polyester substrate (DuPont 454, 4-mil) was coated using the procedure of Example 2, with the following changes: Two monomer syringes and syringe pumps were used, one containing Polydimethoxysiloxane (Gelest PS-012) and the other containing tetra(ethoxy) titanate (DuPont Tyzor ET). The polydimethoxysiloxane syringe was connected to the atomizer via a capillary tube. The tetra(ethoxy) titanate was delivered from the syringe directly to the interior wall of the hot evaporator via a capillary. In this way, the two reactive liquids were delivered separately into the evaporator, evaporated, and mixed as low pressure vapors prior to exiting the coating die, co-condensing and curing on the substrate. The evaporator temperature was 275° C. The coating die was 12-inches wide. The liquid polydimethoxysiloxane flow rate to the atomizer was 0.938 ml/min and the tetra(ethoxy) titanate flow rate to the evaporator wall was 0.1 ml/min. The substrate line speed was 12 fpm. The nitrogen flow into the atomizer was 10 sccm. From the reflectance data, the thickness and refractive index of the film were calculated to be about 175 nm and 1.50, respectively, at a wavelength of 1050 nm.

### Example 12

### Methyltriacetoxy Silane

A polyester substrate (DuPont 454) was coated using the procedure of Example 2, with the following changes: The coating material was methyltriacetoxy silane (a solid at room temperature). The material was melted at 50° C. and loaded into a heated syringe (50° C.) after degassing. The water vapor pressure in the chamber was 3.0 Torr. The water vapor flow rate was 2000 sccm. The nitrogen carrier gas flow rate into the evaporator was 200 sccm. The substrate speed was 10.9 fpm.

The reflectance spectrum of PET and the film formed in Example 12 are shown in FIG. 4. The cured methyltriacetoxy silane film has lower reflectance than the uncoated PET substrate, indicating a lower refractive index than that of the PET (n=1.65). The thickness and refractive index of the coating, calculated from the reflectance data, were about 131 nm and 1.45, respectively, at a wavelength of 760 nm.

### Example 13

### Tetra(ethoxy) Titanate and Ethyleneglycol-bisthioglycolate

A polyester substrate (DuPont 453, 4-mil) was coated using the procedure of Example 2, with the following changes: Two monomer syringes and syringe pumps were used, one containing tetra(ethoxy) titanate (DuPont Tyzor ET) and the other containing ethyleneglycol-bisthioglycolate (Sigma-Aldrich). The syringes containing the alkoxides were connected in parallel to enable either syringe separately or both together to pump material to the atomizer. The evaporator temperature was 275° C. The coating die was 12-inches wide. The liquid tetra(ethoxy) titanate flow rate was 0.9 ml/min and the liquid ethyleneglycol-bisthioglycolate flow rate was 0.1 ml/min. The substrate line speed was 16 fpm. The water vapor flow rate into the chamber was 2000 sccm. The nitrogen flow into the atomizer was 10 sccm. The nitrogen carrier gas flow into the evaporator was 200 sccm. The thickness and refractive index of the coating, calculated from the reflectance data, were about 87 nm and 1.82, respectively, at a wavelength of 635 nm.

### Examples 14 and 15

### Tetra(ethoxy) Titanate and Tripropyleneglycol Diacrylate

A polyester substrate (DuPont 454, 4-mil) was coated, as in Example 2, with the following changes: Two monomer syringes and syringe pumps were used, one containing tetra(ethoxy) titanate (DuPont Tyzor ET) and the other containing a mixture of 97% tripropyleneglycol diacrylate (Sartomer SR-306) and 3% photoinitiator Darocur 1173 (Ciba). In example 14, the liquid streams from both syringes were joined together just before entering the atomizer, enabling the metal alkoxide and acrylate materials to mix inline as liquids prior to atomization and evaporation. In example 15, the liquid streams from the two syringes were kept separate. Each liquid stream was directed to a separate atomizer mounted in separate evaporators. The evaporated metal alkoxide and acrylate materials were mixed as vapors and exited one coating die prior to condensation onto the substrate. The coating die was 12-inches wide. The nitrogen flow into each atomizer was 10 sccm.

The remaining process conditions, coating thickness and refractive index for Examples 14 and 15 are described in Table 3. Note that the coating of sample 14 was thick enough to have two reflection maxima in the spectral range 350-1250 nm. Thus, two separate calculations to estimate refractive index and thickness were performed on these data and both calculations are recorded in Table 3.

TABLE 3
Process Conditions and Coating Characterization.

| | | | SR-306 + | | | | |
|---|---|---|---|---|---|---|---|
| | | | Darocur | | | | |
| | | Tyzor ET | 1173 Flow | Line | | Coating | Coating |
| Example | Mixing | Flow rate | rate | speed | Wavelength | Index of | Thickness |
| No. | State | (ml/min) | (ml/min) | (fpm) | % Rₘₐₓ (nm) | Refraction | (nm) |
| 14 | Liquid | 0.637 | 0.113 | 8 | 450 | 1.87 | 181 |
| | | | | | 1120 | 1.75 | 160 |
| 15 | Vapor | 0.9 | 0.1 | 16 | 745 | 1.73 | 108 |

### Example 16

### Tetra(ethoxy) Titanate and Phenylthioethylacrylate with Pentaerythritol Triacrylate

A polyester substrate (DuPont 454, 4-mil) was coated using the procedure of Example 2, with the following changes: Two monomer syringes and syringe pumps were used, one containing tetra(ethoxy) titanate (DuPont Tyzor ET) and the other containing a mixture of 82.5% phenylthioethylacrylate (Bimax PTEA), 14.5% pentaerythritol triacrylate (San Ester Viscoat 300 PETA) and 3% photoinitiator Darocur 1173 (Ciba). The syringes were connected in parallel to enable either syringe separately or both together to pump material to the atomizer. The evaporator temperature was 275° C. The coating die was 12-inches wide. The liquid Tyzor ET flow rate was 0.675 ml/min and the liquid acrylate mixture flow rate was 0.075 ml/min. The substrate line speed was 8 fpm. The nitrogen flow into the atomizer was 10 sccm. The thickness and refractive index of the coating, calculated from the reflectance data, were about 161 nm and 1.96, respectively, at a wavelength of 420 nm.

### Example 17

### Tetra(ethoxy) Titanate and Darocur 1173

A polyester substrate (DuPont 454, 4-mil) was coated using the procedure of Example 2, with the following changes: The substrate was attached to the process drum. Tyzor ET (8.5 g) was mixed with 1.5 g of 2-hydroxy-2-methyl-1-phenyl-1-propanone (Darocur 1173 from Ciba) in the nitrogen-purged glove box, prior to vacuum degassing and loading into the syringe. The substrate (PET) was plasma-treated with a water-vapor plasma at a pressure of 300 mtorr, water vapor flowrate of 500 sccm, net plasma power of 600 W at a frequency of 400 kHz, with the process drum rotating for 1 drum revolution with the sample passing the plasma source at 40 fpm. After the plasma treatment, the evaporator was heated to 200° C. and the process drum temperature was set to 61° F. The chamber was filled with water vapor and nitrogen to a pressure of 2.0 Torr with a water vapor flow of 1000 sccm and a nitrogen flow of 77 sccm (into the atomizer and evaporator). The coating die was 12-inches wide. The liquid (Tyzor ET and Darocur 1173) flow rate was 1.0 ml/min. The sample was rotated past the vapor coating die at a speed of 15 fpm for 1 revolution to condense the liquid layer of Tyzor ET and Darocur 1173. Then the process drum was heated to 150° F. and the chamber pressure increased to 8 Torr (with a flow of 3000 sccm water vapor and 210 sccm nitrogen). The sample was exposed to this continuous flow of water vapor for 30 minutes. The thickness and refractive index of the coating, calculated from the reflectance data, were about 79 nm and 1.90, respectively, at a wavelength of 600 nm.

### Example 18

### Tetra(ethoxy) Titanate on Metallized PET

A polyester substrate (DuPont 454) was coated using the procedure of Example 1, with the following changes: The substrate surface was sputter-coated with a thin layer of chromium (˜5 nm) prior to (in a previous coater pass) the application of the tetra(ethoxy) titanate. No surface plasma treatment was applied before the titanate coating. The process drum temperature was 25° F. The pressure of the water vapor in the chamber was controlled to 1.5 Torr by the throttle valve. The substrate line speed was varied between 13 and 30 fpm.

### Examples 19-21

### Tetra(ethoxy) Titanate on Coated PET

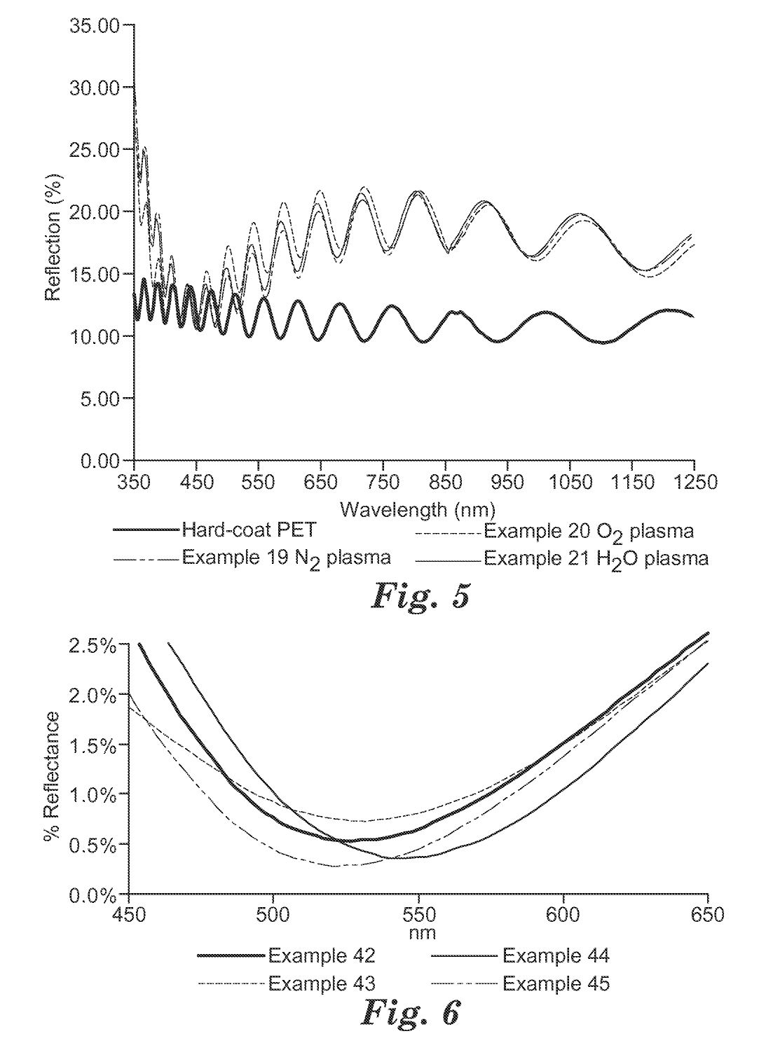

A polyester substrate (DuPont 454) was coated, as described in Example 2, with the following changes: The substrate was a 5-mil thick clear PET substrate with a surface coating (hard-coat formulation containing acrylate materials and SiO₂ particles). The gas/vapor used in the first-pass plasma pretreatment was varied: in Example 19 the gas was nitrogen, in Example 20 the gas was oxygen, and in Example 21 the gas was water vapor. The substrate speed for the tetra(ethoxy) titanate deposition was 14 fpm. The liquid Tyzor ET flow rate was 0.75 ml/min. The nitrogen flow into the atomizer was 7.5 sccm. The coating die was 12-inches wide. The reflectance spectra of the samples from Examples 19-21 and the PET support are shown in FIG. 5.

### Example 22

### Tetra(ethoxy) Titanate with UV Pretreatment

A polyester substrate (DuPont 453 2-mil) was coated using the procedure of Example 1, with the following changes: The first pass plasma pretreatment gas was nitrogen. In the second pass, the throttle valve kept the chamber pressure (H₂O vapor) at 0.3 Torr. In the second pass through the coater the plasma-treated substrate was exposed to UV light for about 4 seconds (in the presence of 0.3 Torr water vapor) immediately before the tetra(ethoxy) titanate deposition. Two low-pressure-mercury-arc lamps were used, generating UV light with primary emission lines at 185 nm and 254 nm wavelengths. Also in the second pass, the coated substrate was exposed to 0.3 Torr water vapor plasma (650 W, 400 kHz) for about 12 seconds immediately after deposition of the titanate. The thickness and refractive index of the coating, calculated from the reflectance data, were about 85 nm and 1.78, respectively.

### Examples 23-26

### Tetra(ethoxy) Titanate on CrOₓ-Coated PET

A polyester substrate (DuPont 453-2 mil) was coated as follows:
Coater pass 1 was deposition of an acrylate layer, using the following sequence and deposition-curing equipment and parameters:
   The acrylate material was a mixture of Ebecryl 130 (Cytec-73.5%) and Lauryl Acrylate (Sartomer Chemicals-24.5%) with Photoinitiator (Darocur 1173-Ciba Specialty Chemicals-2%).
   The flow of acrylate mixture was 1.0 ml/minute.
   The evaporator temperature was 275° C.
   The drum temperature was 25° F.
   The substrate speed was 34 fpm.
   The acrylate layer was cured by exposure to UV lamps (2 low-pressure-mercury-arc lamps emitting 185 and 254 nm wavelengths as described in Example 22 and 3 low-pressure-mercury-arc lamps emitting the 254 nm wavelength only).
   Same pass plasma pretreatment of surface was with N₂ plasma at 0.3 Torr, power set to 340 W, and 400 kHz.
Coater pass 2 was UV lamps post-cure at 10 fpm of selected substrate regions.
Coater pass 3 was sputter deposition of a CrOₓ (˜1-2 nm) layer in selected substrate regions (see Table 4, below).
Coater pass 4 was a substrate rewind pass.
Coater pass 5 was an H₂O plasma treatment pass of selected substrate regions at 0.3 Torr, 40 fpm and 400 W at 400 kHz (see Table 4, below).
Coater pass 6 was tetra(ethoxy) titanate deposition using the procedure of Example 1, except at 9 fpm, and with the inclusion of IR lamp post-heating of the surface immediately following the deposition zone.
   Table 4 summarizes the processing conditions for examples 23-26:

TABLE 4
Process Conditions

| | | CrOₓ (~1-2 nm) layer | H₂O Plasma pre- |
|---|---|---|---|
| | | between acrylate and | treatment before |
| Example | Sample | tetra(ethoxy) titanate | tetra(ethoxy) titanate |
| No. | Reference | layers | layer |
| 23 | L | No | Yes |
| 24 | M | Yes | Yes |
| 25 | N | No | No |
| 26 | O | yes | No |

### Example 27

### Tetra(ethoxy) Titanate with Acetic Acid/Water Cure

A polyester substrate (DuPont 454 4 mil) was coated using the procedure of Example 1, with the following changes: Two monomer syringes and syringe pumps were used, each containing tetra(ethoxy) titanate (DuPont Tyzor ET). The syringes containing the alkoxide were in parallel and each operated at 0.5 ml/min, generating a total liquid flow rate of 1.0 ml/min to the atomizer. The temperature-controlled flask contained 3% acetic acid in water. The pressure of the water and acetic acid vapor in the chamber was controlled to 2 Torr by the throttle valve. The thickness and refractive index of the coating, calculated from the reflectance data, were about 49 nm and 1.92, respectively.

### Example 28

### Tetra(ethoxy) Titanate 0.2 Torr Water

A polyester substrate (DuPont 454 4-mil) was coated using the procedure of Example 1, with the following change: The pressure of the water vapor in the chamber was controlled to 0.2 Torr by the throttle valve. The thickness and refractive index of the coating, calculated from the reflectance data, were about 87 nm and 1.79, respectively.

### Examples 29-32 Tetra(ethoxy) Titanate with varying Water Pressure

A polyester substrate (DuPont 454 4-mil) was coated, as in Example 2, with the following changes: The evaporator temperature was 150° C. The coating die was 12-inches wide. The water vapor flow rate was 3000 sccm. The flow rate of the nitrogen carrier gas entering the evaporator was 200 sccm. The line speed was 21 fpm. The pressure of the water vapor in the chamber was varied as recorded in Table 5, below:

TABLE 5
Process Conditions and Coating Characterization
for Examples 29-32.

| Exam- | H2O Pressure | Wavelength | Coating Index | Coating |
|---|---|---|---|---|
| ple No. | (Torr) | % Rₘₐₓ (nm) | of Refraction | Thickness (nm) |
| 29 | 8 | 380 | 1.97 | 48 |
| 30 | 5 | 525 | 1.85 | 71 |
| 31 | 2 | 760 | 1.74 | 109 |
| 32 | 1 | 650 | 1.76 | 92 |

### Example 33

### Tetra(isopropoxy) Titanate

A polyester substrate (DuPont 454) was coated using the procedure of Example 3, with the following change: During the second pass (tetra(isopropoxy) titanate deposition) the coated substrate was heated to ˜140° F. in the presence of 1.0 Torr H₂O vapor by 5 second exposure to two IR lamps just prior to substrate windup. The thickness and refractive index of the coating, calculated from the reflectance data, were about 67 nm and 1.85, respectively.

### Example 34

### Tetra(isopropoxy) Titanate with H₂O Plasma

A polyester substrate (DuPont 454) was coated, as in Example 3, with the following change: The coated substrate was exposed to 1.0 Torr water vapor plasma (500 W, 400 kHz) for about 12 seconds immediately after deposition of the titanate. The thickness and refractive index of the coating, calculated from the reflectance data, were about 69 nm and 1.78, respectively.

### Example 35

### Tetra(isopropoxy) Titanate with Heat Treatment

The coated substrate prepared using the procedure of Example 33 was placed in an oven at 70° C. for 60 minutes. After heating, the optical reflectance spectrum was obtained. The thickness and refractive index of the coating, calculated from the reflectance data, were about 61 nm and 1.95, respectively.

### Examples 36 and 37

### Tetra(ethoxy) Titanate with Heat Treatment

A polyester substrate (DuPont 454) was coated using the procedure of Example 1, with the following changes: The process drum temperature was about 30° F. After coating, the substrate was post-treated in the process chamber in a 0.3 Torr nitrogen environment, at a substrate speed of 10 fpm. The post-treatment involved heating the film coated substrate on the process drum at 158° F. the second sample (Example 37) was exposed for 18 seconds to the UV lamps described in Examples 23-26. The post-process conditions, coating thickness and refractive index for Examples 36-37 are described in Table 6, below.

TABLE 6
Process Conditions and Coating Characterization.

| | Post-treatment | | Coating | |
|---|---|---|---|---|
| Exam- | Drum Temp | Post-treatment | Index of | Coating |
| ple No. | (° F.) | Exposure to UV | Refraction | Thickness (nm) |
| 36 | 158 | No | 1.81 | 77 |
| 37 | 158 | Yes | 1.82 | 77 |

### Example 38

### Tetra(isopropoxy) Titanate with IR Heat Treatment

A polyester substrate (DuPont 454) was coated using the procedure of Example 33, with the following changes: The web speed during the second pass (titanate layer deposition) was 15 fpm. In a third pass through the chamber, the titanate coating was heated to a temperature above 150° F. in the presence of 0.3 Torr water vapor by 12 seconds exposure to two IR lamps. The thickness and refractive index of the coating, calculated from the reflectance data, were about 71 nm and 1.86, respectively.

### Example 39

### Tetra(isopropoxy) Titanate with H₂O Plasma Treatment

A polyester substrate (DuPont 454) was coated using the procedure of Example 3, with the following changes: In a third pass through the coater, the tetra(isopropoxy) titanate coating was exposed to 0.3 Torr water vapor plasma post-treatment (500 W, 400 kHz) for 12 seconds (15 fpm), with the drum temperature during the plasma post-treatment controlled at 63° F. There was no heating by IR lamps during the third pass. The thickness and refractive index of the coating, calculated from the reflectance data, were about 70 nm and 1.85, respectively.

### Example 40 and 41

### Tetra(ethoxy) Titanate with Plasma Treatment

A polyester substrate (DuPont 454) was coated using the procedure of Example 1, with the following changes: In a third pass through the chamber, the tetra(ethoxy) titanate coating was exposed to a plasma post-treatment (500 W, 400 kHz, 0.3 Torr) for 4 minutes (substrate stopped), with the drum temperature during the plasma post-treatment controlled to 60° F. The plasma gas was either oxygen or argon, as indicated for Examples 40 and 41 in Table 7, below.

TABLE 7
Process Conditions and Coating Characterization.

| | | Coating Index of | Coating |
|---|---|---|---|
| Example No. | Plasma Gas | Refraction | Thickness (nm) |
| 40 | O₂ | 1.82 | 91 |
| 41 | Ar | 1.86 | 70 |

### Examples 42-45

### Two-Layer Antireflection Article Construction Tetra(ethoxy) Titanate and Acrylate

A polyester substrate (DuPont 454) was coated, in the following sequence, to form two-layer antireflection article constructions:
The first coater pass was an H₂O plasma treatment at 0.3 Torr chamber pressure, 400 watts net power, 400 kHz, and at 40 fpm.
The second coater pass was deposition of tetra(ethoxy) titanate using the procedure of Example 1, except that substrate speed was varied, in discrete intervals, over the course of the coater pass (see Table 8, below).
The third coater pass was for the deposition of an acrylate layer, using the following sequence and deposition-curing equipment and parameters:
   The acrylate material was a mixture of Ebecryl 130 (Cytec-73.5%) and Lauryl Acrylate (Sartomer Chemicals-24.5%) with Photoinitiator (Darocur 1173 Ciba Specialty Chemicals-2%).
   The liquid acrylate formulation flow rate was 1.0 ml/minute.
   The evaporator temperature was 275° C.
   The drum temperature was 25° F.
   The substrate speed was varied, in discrete intervals, over the course of the coater pass (see Table 8, below).
   The acrylate layer was cured by exposure to UV lamps as described in Examples 23-26.
   Same pass plasma pretreatment of surface was with N₂ plasma at 0.3 Torr, 400 kHz, and power (W) varied as 10× that of substrate speed (fpm).

TABLE 8
Process Conditions.

| Exam- | | R | | | |
|---|---|---|---|---|---|
| ple | Sample | (reflectance) | Rᵥᵢₛ (450-650 nm) | Titanate | Acrylate |
| No. | Ref. | % min. | % Avg. | fpm | fpm |
| 42 | H | 0.53 | 1.3 | 16 | 83.6 |
| 43 | M | 0.73 | 1.3 | 15 | 86.5 |
| 44 | O | 0.39 | 1.3 | 17 | 86.5 |
| 45 | P | 0.28 | 1.1 | 17 | 83.6 |

The reflectance spectra of coated sections of the films prepared in Examples 42-45 are included in FIG. 6. Removal of back surface reflection from the polyester substrate was accomplished by lightly abrading the back surface and applying black tape (Yamato Co., Japan).

### Example 46

### Two-Layer Antireflection Article Construction Tetra(ethoxy) Titanate and Methyltriacetoxy Silane

A polyester substrate (DuPont 454 4-mil) was coated, in the following sequence, to form two-layer antireflection article constructions:
The first coater pass was an H₂O plasma treatment at 0.3 Torr chamber pressure, 400 watts net power, 400 kHz, and at 40 fpm.
The second coater pass was deposition of tetra(ethoxy) titanate using the procedure of Example 2, with the following exception:
   the substrate speed was 16 fpm.
A second coating layer of methyltriacetoxy silane was later deposited onto the titanate layer. The methyltriacetoxy silane layer was deposited using the procedure of Example 12, with the following exception:
   The substrate speed was 22.7 fpm.
After deposition of the two-layer construction, the coated substrate was treated in an oven for 24 hrs at 70° C.

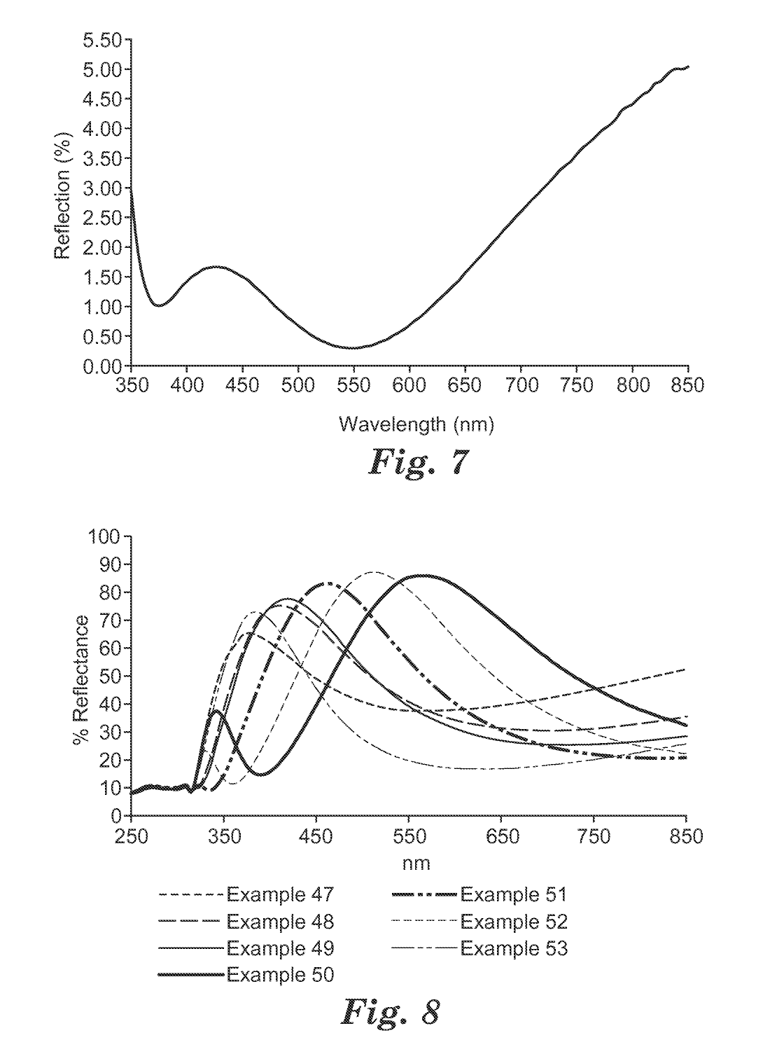

The reflectance spectrum of the coated substrate is shown in FIG. 7. Removal of back surface reflection from the polyester substrate was accomplished by lightly abrading the back surface and applying black tape (Yamato Co., Japan).

### Examples 47-53

### Formation of Color-Shifting Articles

A polyester substrate (DuPont 454) was coated using the procedure of Example 18, with the following changes: In a third pass through the coater a layer of silver (˜40 nm) was sputter-coated atop the titanate layer, completing a three layer chromium-titanate-silver optical stack which, when viewed from the uncoated side of the polyester substrate, exhibits reflected color. Table 9 summarizes the line speeds used during the titanate deposition passes for Examples 47-53.

TABLE 9
Process Conditions.

| Example No. | Sample location (ft.) | Fpm |
|---|---|---|
| 47 | 75 | 30 |
| 48 | 125 | 22 |
| 49 | 175 | 18 |
| 50 | 223 | 13 |
| 51 | 275 | 14 |
| 52 | 325 | 15 |
| 53 | 375 | 15 |

Reflectance spectra of Examples 47-53 are included in FIG. 8. The spectral appearance (“color”) of the sections is primarily determined by the varied thickness of the titanate layer (controlled by substrate speed changes during titanate deposition).

### Example 54

### Fluorinated Polyether Coating

A fluorinated polyether oligomer functionalized with trimethoxy silane functional groups at each end and the general formula:

X—CF₂O(CF₂O)ₘ(C₂F₄O)ₙCF₂—X

where X═CONHCH₂CH₂CH₂Si(OCH₃)₃, m is about 10, n is about 10, and having an average molecular weight of about 2000 was used for coating a glass plate.

The fluorinated trialkoxysilane polyether oligomer was coated onto anti-reflectance coated (AR) glass (TDAR) from Viracon in a system shown schematically in FIG. 2. The oligomer was atomized and evaporated by the methods such as those described in U.S. Pat. No. 6,045,864. The liquid flow rate into the atomizer was 0.075 ml/min. The hot nitrogen flow into the atomizer was 44 lpm at a temperature of 186° C. The evaporator zone temperature was 162° C. The substrate was exposed to the vapor flow exiting the diffuser for 5 seconds to form a very thin, condensed liquid coating on the AR glass. The liquid film was cured by exposure to atmospheric water vapor in an oven at 110° C. for 5 minutes.

After curing, the coating had ink repellency (Sharpie® pen ink beaded up) and the ink was easily removed with a dry wipe. The durability of the coating was tested by mechanically rubbing the coating with 24 layers of cheese cloth (grade 90) under a weight of 1 kg for 2500 rub cycles. The coating maintained the ink repellency (Sharpie® pen ink beaded up) and the ink was easily removed with a dry wipe after the cheese cloth rubbing.

### Example 55

### Fluorinated Polyether Coating

A polycarbonate plate 12 inches×9 inches was coated with the fluorinated trialkoxysilane polyether oligomer, using the procedure of Example 54, with the following changes: the diffuser was replaced with a slot coating die 10 inches wide, the liquid monomer flow rate was 0.10 ml/min, the nitrogen flow to the atomizer was 50 lpm at 300° C., the evaporation zone temperature was 300° C., and the substrate was moved past the coating die slot at 1 inch/second. The liquid coating was cured by exposure to a hot flux of water vapor from a catalytic combustion source. The 12×4 inch catalytic burner (Flynn Burner Corp.) was supported by combustible mixture consisting of 385 ft³/hr of dried, dust-filtered air and 40 ft³/hr of natural gas, which provided a flame power of 40,000 Btu/hr-in. The flame equivalence ratio was 1.00. The gap between the catalytic burner and the coated substrate was about 2 inches. The exposure time was less than 2 seconds. After curing, the coating was repellent to solvent-based ink.

Illustrative embodiments of this disclosure are discussed and reference has been made to possible variations within the scope of this disclosure. These and other variations and modifications in the disclosure will be apparent to those skilled in the art without departing from the scope of the disclosure, and it should be understood that this disclosure and the claims shown below are not limited to the illustrative embodiments set forth herein.

1. A method for forming an inorganic or hybrid organic/inorganic layer on a substrate, which method comprises:
vaporizing a metal alkoxide;
condensing the metal alkoxide to form a layer atop the substrate; and
contacting the condensed metal alkoxide layer with water to cure the layer.

2. (canceled)

3. The method of claim 1, further comprising exposing the inorganic or hybrid organic/inorganic layer to a heat treatment.

4-6. (canceled)

7. The method of claim 1, comprising contacting the metal alkoxide layer with liquid water.

8. The method of claim 1, comprising contacting the metal alkoxide layer with water vapor.

9. The method of claim 8, comprising contacting the metal alkoxide layer with a plasma containing water vapor.

10. The method of claim 1, wherein the metal alkoxide comprises an alkoxide of aluminum, antimony, arsenic, barium, bismuth, boron, cerium, gadolinium, gallium, germanium, hafnium, indium, iron, lanthanum, lithium, magnesium, molybdenum, neodymium, phosphorus, silicon, sodium, strontium, tantalum, thallium, tin, titanium, tungsten, vanadium, yttrium, zinc, zirconium, or a mixture thereof.

11. The method of claim 10, wherein the metal alkoxide comprises an alkoxide of titanium, zirconium, silicon, aluminum, tantalum, barium, tin, indium, zinc, gallium, bismuth, magnesium, strontium, boron, cerium, hafnium, neodymium, lanthanum, tungsten, or a mixture thereof.

12. The method of claim 11, wherein the metal alkoxide comprises tetra(ethoxy) titanate, tetra(isopropoxy) titanate, tetra(n-propoxy)titanate, polydimethoxysiloxane, methyltriacetoxy silane, tetra(n-propoxy) zirconate, tetra(n-butoxy) zirconate, or a mixture thereof.

13. The method of claim 10, wherein the metal alkoxide comprises a trialkoxysilane.

14-15. (canceled)

16. A method for forming a hybrid organic/inorganic layer on a substrate, which method comprises:
vaporizing a metal alkoxide;
vaporizing an organic compound;
condensing the vaporized alkoxide and vaporized organic compound to form a layer atop the substrate; and
curing the layer.

17. (canceled)

18. The method of claim 16, wherein the vaporized alkoxide and vaporized compound are vaporized separately and mixed in the vapor phase before condensing atop the substrate.

19. The method of claim 16 wherein the alkoxide and the organic compound are vaporized together.

20. (canceled)

21. The method of claim 16, wherein the organic compound comprises an alcohol, carboxylic acid, ester, acid anhydride, acetyl halogen, thiol, or amine.

22. The method of claim 21, wherein the ester comprises an acrylate.

23. The method of claim 22, wherein the acrylate is cured simultaneously with the metal alkoxide curing.

24. The method of claim 22, wherein the acrylate and metal alkoxide are cured separately.

25. A film comprising at least one inorganic or hybrid organic/inorganic layer formed by the method of claim 1.

26. The film of claim 25, wherein the inorganic or hybrid organic/inorganic layer provides an article with antireflection properties.

27. The film of claim 25, further comprising at least one additional layer that in combination with the hybrid organic/inorganic layer provides an article with anti-reflective properties.

28. The film of claim 25, further comprising at least one additional layer that in combination with the hybrid organic/inorganic layer provides an article with color-shifting properties.

29. (canceled)

30. An ophthalmic lens comprising the film of claim 27.

31. A security device comprising the color shifting article of claim 28.

32. The device of claim 31 comprising an image.

33. A film comprising at least one hybrid organic/inorganic layer formed by the method of claim 16.

34. The film of claim 33, wherein the hybrid layer comprises an acrylate polymer.

35. The film of claim 33, further comprising at least one additional layer that in combination with the hybrid organic/inorganic layer provides an article with anti-reflective properties.

36. The film of claim 33, further comprising at least one additional layer that in combination with the hybrid organic/inorganic layer provides an article with color-shifting properties.

37. An ophthalmic lens comprising the antireflection film of claim 35.

38. A security device comprising the color shifting article of claim 36.

39-40. (canceled)
